(19) United States
(12) Patent Application Publication
(10) Pub. No.: US 2025/0221126 A1
(43) Pub. Date: Jul. 3, 2025

(54) DISPLAY BACKPLANE AND DISPLAY DEVICE

(71) Applicant: Wuhan China Star Optoelectronics Technology Co., Ltd., Wuhan, Hubei (CN)

(72) Inventor: Wenhao LI, Wuhan, Hubei (CN)

(73) Assignee: Wuhan China Star Optoelectronics Technology Co., Ltd., Wuhan, Hubei (CN)

(21) Appl. No.: 18/851,813

(22) PCT Filed: Jun. 30, 2023
(86) PCT No.: PCT/CN2023/104811

§ 371 Date: Sep. 27, 2024

(30) Foreign Application Priority Data
Sep. 30, 2022 (CN) 202211211870.4

(51) Int. Cl. H10H 29/34; H10H 29/49

(52) U.S. Cl. CPC H10H 29/34; H10H 29/49

(57) ABSTRACT

A display backplane and a display device are provided in the application. The display backplane includes light-emitting unit groups arranged in a first direction. Each light-emitting unit group includes first light-emitting units and second light-emitting units arranged alternately in a second direction. Sizes of the first light-emitting units in the first direction are greater than sizes of the second light-emitting units in the first direction, and sizes of the first light-emitting unit in the second direction are less than sizes of the second light-emitting units in the second direction.

### TECHNICAL FIELD

The present application relates to the field of display technologies, and more particularly, to a display backplane and a display device.

### BACKGROUND

The Mini-Light Emitting Diode (referred briefly to as Mini-LED) technology refers to an LED technology having a size of an area of the light emitting chip ranging from 100 μm to 200 μm. The Mini-LED inherits the characteristics of high efficiency, high brightness, high reliability, and fast response time of the inorganic LED, and has the self-luminescence characteristic without a backlight. And the Mini-LED also has the advantages of energy saving, simple mechanism, small size, and thin size. The Mini-LED has the advantages of longer luminous life, higher brightness, better material stability, no image imprint and the like, and can be applied to the display backplane to realize the light adjustment of the multiple areas of the display device, thereby improving the display effect of the display device.

### SUMMARY

When Mini-LED is used as a backlight source in the prior art, however, as the size of the beads becomes smaller and smaller, there is still a phenomenon of the poor brightness between adjacent Mini-LED beads, thereby resulting in an uneven overall brightness of the display backplane.

Therefore, there is a need for a display backplane and a display device to solve the above-mentioned technical problems.

The present application provides a display backplane and a display device to improve the technical problem of uneven mixing light of light-emitting unit groups in an existing display backplane.

To solve the above problems, the present application provides the following technical solutions.

The application provides a display backplane including a substrate; and a light-emitting layer disposed on the substrate, the light-emitting layer including a plurality of light-emitting unit groups arranged in a first direction, in which each of the light-emitting unit groups includes a plurality of first light-emitting units and a plurality of second light-emitting units arranged alternately in a second direction;

in which sizes of the plurality of first light-emitting units in the first direction are greater than sizes of the plurality of second light-emitting units in the first direction, and sizes of the plurality of first light-emitting unit in the second direction are less than sizes of the plurality of second light-emitting units in the second direction.

In the display backplane provided by the application, ones of the plurality of first light-emitting units and ones of the plurality of second light-emitting units in adjacent two of the plurality of light-emitting unit groups are arranged in a same manner.

In the display backplane provided by the application, ones of the plurality of first light-emitting units and ones of the plurality of second light-emitting units in adjacent two of the plurality of light-emitting unit groups are arranged differently;
in which the ones of the plurality of first light-emitting units and the ones of the plurality of second light-emitting units are alternately arranged in the first direction, and a long-side direction of adjacent two of the ones of the plurality of first light-emitting units is perpendicular to a long-side direction of a corresponding one of the ones of the plurality of second light-emitting units.

In the display backplane provided by the application, a connection line between a center of each of the plurality of first light-emitting units and a center of a corresponding one of the plurality of second light-emitting units in the first direction is parallel to the first direction; and
a connection line between the center of the first light-emitting unit and the center of the corresponding one of the plurality of second light-emitting unit in the second direction is parallel to the second direction.

In the display backplane provided by the application, the light-emitting layer includes a plurality of repeating units each of which includes two of the plurality of first light-emitting units and two of the plurality of second light-emitting units;
in which in each of the plurality of repeating units, in the first direction, a short side of one of the two first light-emitting units that is away from an other one of the two first light-emitting units and a long side of one of the two second light-emitting units adjacent to the one of the two first light-emitting units are aligned in the first direction, in which the long side is away from an other one of the two second light-emitting units;
in the second direction, a long side of one of the two first light-emitting units which is away from the other one of the two first light-emitting units and a short side of one of the two second light-emitting units which is adjacent to the one of the two first light-emitting units are aligned in the second direction, in which the short side of the one of the two second light-emitting units is away from the other one of the two second light-emitting units.

In the display backplane provided by the application, a distance between adjacent two of the plurality of first light-emitting units and a corresponding one of the plurality of first light-emitting units in the first direction is equal to a distance between adjacent two of the plurality of first light-emitting units and a corresponding one of the plurality of second light-emitting units in the second direction.

In the display backplane provided by the application, the display backplane further includes a driving circuit layer disposed between the substrate and the light-emitting layer, and the driving circuit layer includes a thin film transistor and a power supply line;
the first light-emitting units and the second light-emitting units each include a first contact terminal and a second contact terminal, in which the first contact terminal is electrically connected to a source electrode or a drain electrode of the thin film transistor, and the second contact terminal is electrically connected to the power supply line;
in which the first contact terminal and the second contact terminal in the first light-emitting unit are arranged differently from the first contact terminal and the second contact terminal in the second light-emitting unit.

In the display backplane provided by the application, the first contact terminal and the second contact terminal in the first light-emitting unit and the first contact terminal and the second contact terminal in the second light-emitting unit are arranged in the first direction or the second direction;

in which a distance between the first contact terminal and the second contact terminal in the first light-emitting unit is greater than a distance between the first contact terminal and the second contact terminal in the second light-emitting unit.

In the display backplane provided by the application, the first contact terminal and the second contact terminal in the first light-emitting unit are arranged in the second direction, and the first contact terminal and the second contact terminal in the second light-emitting unit are arranged in the first direction.

Correspondingly, the present application further provides a display device including a display backplane including:
a substrate; and
a light-emitting layer disposed on the substrate, the light-emitting layer including a plurality of light-emitting unit groups arranged in a first direction, in which each of the light-emitting unit groups includes a plurality of first light-emitting units and a plurality of second light-emitting units arranged alternately in a second direction;
in which sizes of the plurality of first light-emitting units in the first direction are greater than sizes of the plurality of second light-emitting units in the first direction, and sizes of the plurality of first light-emitting unit in the second direction are less than sizes of the plurality of second light-emitting units in the second direction.

In the display device provided by the application, ones of the plurality of first light-emitting units and ones of the plurality of second light-emitting units in adjacent two of the plurality of light-emitting unit groups are arranged in a same manner.

In the display device provided by the application, ones of the plurality of first light-emitting units and ones of the plurality of second light-emitting units in adjacent two of the plurality of light-emitting unit groups are arranged differently;
in which the ones of the plurality of first light-emitting units and the ones of the plurality of second light-emitting units are alternately arranged in the first direction, and a long-side direction of adjacent two of the ones of the plurality of first light-emitting units is perpendicular to a long-side direction of a corresponding one of the ones of the plurality of second light-emitting units.

In the display device provided by the application, a connection line between a center of each of the plurality of first light-emitting units and a center of a corresponding one of the plurality of second light-emitting units in the first direction is parallel to the first direction; and
a connection line between the center of the first light-emitting unit and the center of the corresponding one of the plurality of second light-emitting unit in the second direction is parallel to the second direction.

In the display device provided by the application, the light-emitting layer includes a plurality of repeating units each of which includes two of the plurality of first light-emitting units and two of the plurality of second light-emitting units;
in which in each of the plurality of repeating units, in the first direction, a short side of one of the two first light-emitting units that is away from an other one of the two first light-emitting units and a long side of one of the two second light-emitting units adjacent to the one of the two first light-emitting units are aligned in the first direction, in which the long side is away from an other one of the two second light-emitting units;

in the second direction, a long side of one of the two first light-emitting units which is away from the other one of the two first light-emitting units and a short side of one of the two second light-emitting units which is adjacent to the one of the two first light-emitting units are aligned in the second direction, in which the short side of the one of the two second light-emitting units is away from the other one of the two second light-emitting units.

In the display device provided by the application, a distance between adjacent two of the plurality of first light-emitting units and a corresponding one of the plurality of first light-emitting units in the first direction is equal to a distance between adjacent two of the plurality of first light-emitting units and a corresponding one of the plurality of second light-emitting units in the second direction.

In the display device provided by the application, the display backplane further includes a driving circuit layer disposed between the substrate and the light-emitting layer, and the driving circuit layer includes a thin film transistor and a power supply line;
the first light-emitting units and the second light-emitting units each include a first contact terminal and a second contact terminal, in which the first contact terminal is electrically connected to a source electrode or a drain electrode of the thin film transistor, and the second contact terminal is electrically connected to the power supply line;
in which the first contact terminal and the second contact terminal in the first light-emitting unit are arranged differently from the first contact terminal and the second contact terminal in the second light-emitting unit.

In the display device provided by the application, the first contact terminal and the second contact terminal in the first light-emitting unit and the first contact terminal and the second contact terminal in the second light-emitting unit are arranged in the first direction or the second direction;
in which a distance between the first contact terminal and the second contact terminal in the first light-emitting unit is greater than a distance between the first contact terminal and the second contact terminal in the second light-emitting unit.

In the display device provided by the application, the first contact terminal and the second contact terminal in the first light-emitting unit are arranged in the second direction, and the first contact terminal and the second contact terminal in the second light-emitting unit are arranged in the first direction.

In the display device provided by the application, an aspect ratio of each of the first light-emitting units or an aspect ratio of each of the second light-emitting units is greater than 1.5:1.

### Beneficial Effect

Beneficial effects of embodiments of the present application are as follows. The present application provides a display backplane and a display device. The display backplane includes a substrate and a light-emitting layer disposed on the substrate. The light-emitting layer includes a plurality of light-emitting unit groups arranged in a first direction. The light-emitting unit groups include a plurality of first light-emitting units and a plurality of second light-emitting units arranged alternately in a second direction. A size of the first light-emitting unit in the first direction is larger than a size of the second light-emitting unit in the first direction, and a size of the first light-emitting unit in the second direction is smaller than a size of the second light-emitting unit in the second direction. According to the display backplane provided in the present invention, the sizes of the first light-emitting units in the first direction are larger than the sizes of the second light-emitting unit in the first direction, and the sizes of the first light-emitting units in the second direction are smaller than the sizes of the second light-emitting units in the second direction, so that the overlapping areas, which are in the first direction, of the light emission patterns of at least a part of the first light-emitting units and the light emission patterns of the second light-emitting units adjacent thereto are approximately consistent with the overlapping areas, in the second direction, of the light emission patterns of at least the part of the first light-emitting units and the light emission patterns of the second light-emitting units adjacent thereto. So, the overall light emission of the display panel is more uniform, thereby reducing a shadow area formed due to insufficient illumination, avoiding the problem of uneven brightness of the display backplane, and further improving the light emission effect of the display backplane.

### BRIEF DESCRIPTION OF THE DRAWINGS

In order that the embodiments or the technical solutions in the prior art may be described more clearly, reference will now be made to the accompanying drawings which are to be used in the description of the embodiments or the prior art. It will be apparent that the accompanying drawings in the description below are merely some of the embodiments of the application, and other drawings may be made to those skilled in the art without involving any inventive effort.

FIG. 1 is a partial schematic diagram of a light-emitting unit of a display backplane according to an embodiment of the present application;

FIG. 2 is another partial schematic diagram of a light-emitting unit of a display backplane according to an embodiment of the present application;

FIG. 3A is yet another partial schematic diagram of a light-emitting unit of a display backplane according to an embodiment of the present application;

FIG. 3B is yet another partial schematic diagram of a light-emitting unit of a display backplane according to an embodiment of the present application;

FIG. 4 is a cross-sectional view of the backplane taken along line A-A in FIG. 3A; and

FIG. 5 is a partial schematic view of a display backplane according to an embodiment of the present application.

### DETAILED DESCRIPTION

The following description of the embodiments is made with reference to the accompanying drawings to illustrate specific embodiments in which the present application may be implemented. The direction terms mentioned in the present application, such as [upper], [lower], [front], [rear], [left], [right], [inner], [outer], [side], and the like, are only directions with reference to the additional drawings. Thus, the directional language is used to describe and understand the present application, and not to limit the present application. In the figures, structurally similar elements are denoted by the same reference numerals.

The present application is further described below with reference to the accompanying drawings and specific examples.

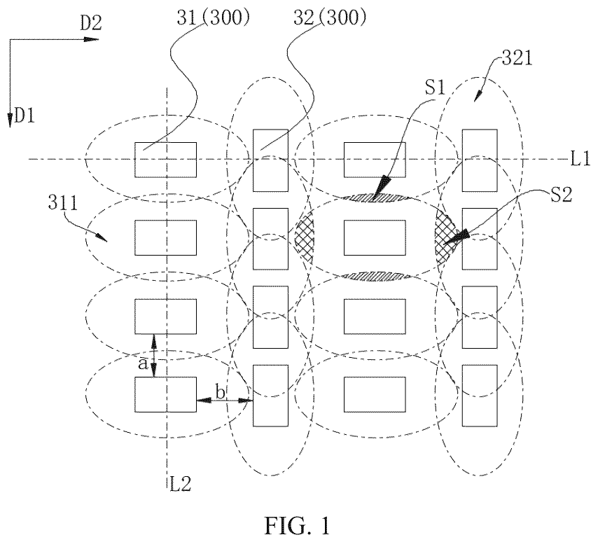

Referring to FIGS. 1 to 5, the present application provides a display backplane including a substrate 100 and a light-emitting layer disposed on the substrate 100. The light-emitting layer includes a plurality of light-emitting unit groups 300 arranged in a first direction D1. The light-emitting unit group 300 includes a plurality of first light-emitting units 31 and a plurality of second light-emitting units 32 arranged alternately in a second direction D2.

A size of the first light-emitting unit 31 in the first direction D1 is larger than a size of the second light-emitting unit 32 in the first direction D1. A size of the first light-emitting unit 31 in the second direction D2 is smaller than a size of the second light-emitting unit 32 in the second direction D2.

According to the display backplane provided in the present application, the size of the first light-emitting unit 31 in the first direction D1 is larger than the size of the second light-emitting unit 32 in the first direction D1, and the size of the first light-emitting unit 31 in the second direction D2 is smaller than the size of the second light-emitting unit 32 in the second direction D2, so that overlapping areas, which are in the first direction D1, of the light emission patterns of at least a part of the first light-emitting units 31 and the light emission patterns of the second light-emitting units 32 adjacent thereto are approximately consistent with the overlapping areas, which are in the second direction D2, of the light emission patterns of at least the part of the first light-emitting units 31 and the light emission patterns of the second light-emitting units 32 adjacent thereto. In this way, the overall light emission from the display backplane is more uniform, thereby reducing a shadow area formed due to insufficient illumination, and further avoiding the problem that the display backplane is uneven in brightness and darkness, and thus improving the light emission effect of the display backplane.

The technical solution of the present application will now be described in connection with specific examples.

### EXAMPLE 1

Referring to FIG. 1, FIG. 1 is a partial schematic diagram of a light-emitting unit of a display backplane according to an embodiment of the present application. The display backplane includes a substrate 100 and a light-emitting layer disposed on the substrate 100. The light-emitting layer includes a plurality of light-emitting unit groups 300 arranged in a first direction D1. The light-emitting unit group 300 includes a plurality of first light-emitting units 31 and a plurality of second light-emitting units 32 arranged alternately in a second direction D2. The size of the first light-emitting unit 31 in the first direction D1 is greater than the size of the second light-emitting unit 32 in the first direction D1. The size of the first light-emitting unit 31 in the second direction D2 is less than the size of the second light-emitting unit 32 in the second direction D2.

In one embodiment of the present application, both the first light-emitting unit 31 and the second light-emitting unit 32 are rectangular, and the second direction D2 is perpendicular to the first direction D1.

A long-side direction in which long sides of the first light-emitting unit 31 are arranged is perpendicular to a long-side direction in which long sides of the second light-emitting unit 32 are arranged, when viewed from a top view of the display backplane.

Specifically, in the embodiments of the present application, the long sides of the first light-emitting unit 31 are arranged in the second direction D2, and short sides of the second light-emitting unit 32 are arranged in the second direction D2.

In the embodiments of the present application, since both the first light-emitting unit 31 and the second light-emitting unit 32 are rectangular, both the first light-emitting unit 31 and the second light-emitting unit 32 emit elliptical light spots. This is because the light pattern of the first light-emitting unit 31 in the long-side direction is inconsistent with the light pattern of the first light-emitting unit 31 in the short-side direction; or the light pattern of the second light-emitting unit 32 in the long-side direction is inconsistent with the light pattern of the second light-emitting unit 32 in the short-side direction. Further, the light pattern in the long-side direction is larger than the light pattern in the short-side direction at the same angle. In this way, the elliptical light spot with a longer side in the long-side direction and a shorter side in the short-side direction is formed.

Specifically, the first light-emitting unit 31 emits a first elliptical light pattern 311 in the second direction D2, and the second light-emitting unit 32 emits a second elliptical light pattern 321 in the first direction D1. An area of the first elliptical light pattern 311 is equal to an area of the second elliptical light pattern 321.

In the embodiments of the present application, the first light-emitting units 31 and the second light-emitting units 32 in two adjacent light-emitting unit groups 300 are arranged in the same manner. In this arrangement, an arrangement distance between the first light-emitting unit 31 and the second light-emitting unit 32 adjacent thereto in each row of the light-emitting unit group 300 may be increased, thereby reducing the number of light-emitting units in each row of the light-emitting unit group 300, and further reducing the manufacturing cost of the display backplane. At the same time, the overall light emission of the display backplane is more uniform, shadow areas formed due to insufficient illumination are reduced, so that the problem of uneven brightness and darkness of the display backplane is reduced, and thus the light emission effect of the display backplane is improved.

In the embodiments of the present application, in the same light-emitting unit group 300, the light emission pattern of the first light-emitting unit 31 partially intersects the light emission pattern portion of the second light-emitting unit 32 adjacent thereto. The light, which is in the second direction D2, of the elliptical light pattern emitted by the first light-emitting unit 31 and the light, which is in the first direction D1 of the elliptical light pattern emitted by the adjacent second light-emitting unit 32 intersects and complements with each other, thereby improving the light emission effect of the display backplane.

Specifically, in the first direction D1, the light emission pattern of the first light-emitting unit 31 and the light emission patterns of the two first light-emitting units 31 adjacent thereto have overlapping portions S1. In the second direction D2, the light emission pattern of the first light-emitting unit 31 and the light emission patterns of the two second light-emitting units 32 adjacent thereto have overlapping portions S2. In embodiments of the present application, it may increase the area of the overlapping portion SI of the light emission pattern of the second light-emitting unit 32 in the first direction D1, and the area of the overlapping portion S2 of the light emission pattern of the first light-emitting unit 31 in the second direction D2 is decreased, with respect to a regular arrangement in the prior art (a plurality of the first light-emitting units 31 are arranged at intervals in the first direction D1 and in the second direction D2). In this way, the overlapping areas, which are in the first direction D1, of the light emission patterns of at least a part of the first light-emitting units 31 and the light emission patterns of the second light-emitting units 32 adjacent thereto are approximately consistent with the overlapping areas, which are in the second direction D2, of the light emission patterns of at least the part of the first light-emitting unit 31 and the light emission patterns of the second light-emitting units 32 adjacent thereto.

When an aspect ratio of the first light-emitting unit 31 or an aspect ratio of the second light-emitting unit 32 is greater than 1.5:1, the light spot emitted by the first light-emitting unit 31 or the second light-emitting unit 32 is elliptical in shape, so that the light of the adjacent light-emitting units is mutually complementary, and thus the overall light emission of the display backplane is more uniform.

In the present embodiment, as shown in FIG. 1, central positions of the light-emitting units in the two adjacent rows of light-emitting unit groups 300 correspond to each other in sequence. The light-emitting units in the two adjacent rows of light-emitting unit groups 300 correspond to each other in sequence, so that intersect correspondence does not occur. When the light emitted from the first light-emitting unit 31 or the second light-emitting unit 32 is non-uniform, the light of the adjacent light-emitting units intersects and thus the brightness is relatively high to form a bright spot area. The light spot of the first light-emitting unit 31 or the second light-emitting unit 32 cannot irradiate and thus the brightness is relatively low to form a shadow area. So, the backlight image may have uneven brightness. The central positions of the first light-emitting units 31 or the second light-emitting units 32 of the two adjacent rows of light-emitting unit groups 300 are arranged in a one-to-one correspondence (that is, in the second direction D2, a connection line L1 between a center of the first light-emitting unit 31 and a center of the second light-emitting unit 32 is arranged in the second direction D2, and in the first direction D1, a connection line L2 between the center of the first light-emitting unit 31 and the center of the second light-emitting unit 32 is arranged in the first direction D1), and the long-side direction of the first light-emitting unit 31 is perpendicular to the long-side direction of the second light-emitting unit 32, so that the light, in the second direction D2, of the elliptical light pattern emitted by the first light-emitting unit 31 and the light, in the first direction D1, of the elliptical light pattern emitted by the adjacent second light-emitting unit 32 are mutually complementary, thereby making the overall light emission of the display backplane more uniform.

In the present embodiment, a distance a between adjacent two first light-emitting units 31 and the second light-emitting unit 32 in the first direction D1 is equal to a distance b between adjacent two first light-emitting units 31 and the second light-emitting unit 32 in the second direction D2. This arrangement enables the light spots emitted by the first light-emitting units 31 or the second light-emitting units 32 to be more evenly distributed in the display backplane, and further improves the light emission effect of the display backplane.

In the embodiment of the present application, both the first light-emitting unit 31 and the second light-emitting unit 32 are mini light emitting diode (referred briefly to as Mini-LED) chips. Here, the Mini-LED chip refers to an LED chip having a size between 50˜200 μm. The first light-emitting unit 31 and the second light-emitting unit 32 may be used as a backlight of a display device, or may be used as a self-luminescent layer of the display device.

In view of the technical problem of uneven light mixing of the light-emitting unit groups 300 in a conventional display backplane, the present application provides the display backplane including the substrate 100 and the light-emitting layer provided on the substrate 100. The light-emitting layer includes the plurality of light-emitting unit groups 300 arranged in the first direction D1. The light-emitting unit group 300 include a plurality of first light-emitting units 31 and a plurality of second light-emitting units 32 arranged alternately in a second direction D2. A size of the first light-emitting unit 31 in the first direction D1 is larger than a size of the second light-emitting unit 32 in the first direction D1, and a size of the first light-emitting unit 31 in the second direction D2 is smaller than a size of the second light-emitting unit 32 in the second direction D2. According to the display backplane provided in the present application, the size of the first light-emitting unit 31 in the first direction D1 is larger than the size of the second light-emitting unit 32 in the first direction D1, and the size of the first light-emitting unit 31 in the second direction D2 is smaller than the size of the second light-emitting unit 32 in the second direction D2. In this way, the long-side direction of the plurality of the first light-emitting units 31 is perpendicular to the long-side direction of the plurality of the second light-emitting units 32, so that the overlapping areas, which are in the first direction D1, of the light emission patterns of at least a part of the first light-emitting units 31 and the light emission patterns of the second light-emitting units 32 adjacent thereto are approximately consistent with the overlapping areas, which are in the second direction D2, of the light emission patterns of at least the part of the first light-emitting units 31 and the light emission patterns of the second light-emitting units 32 adjacent thereto. Accordingly, the overall light emission of the display backplane is more uniform, thereby reducing a shadow area formed due to insufficient illumination, further avoiding the problem that the display backplane is uneven in brightness and darkness, and thus improving the light emission effect of the display backplane.

### EXAMPLE 2

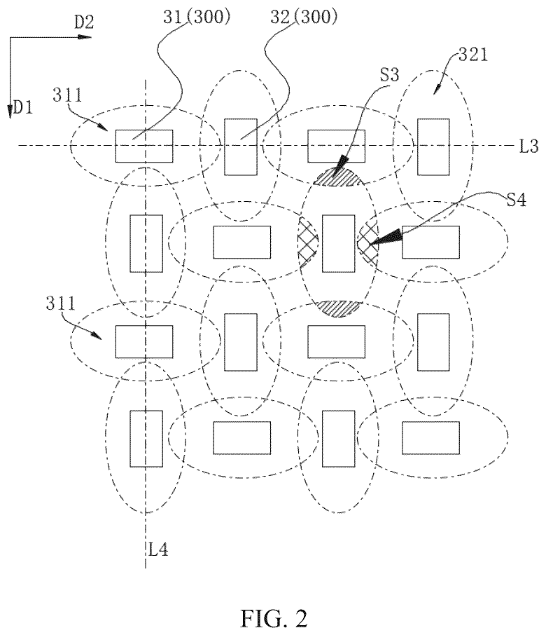

Referring to FIG. 2, FIG. 2 is another partial schematic diagram of a light-emitting unit of a display backplane according to an embodiment of the present application. The structure of the display backplane in Example 2 of the present application is the same as or similar to that of the display backplane in Example 1 of the present application, except that the arrangements of the first light-emitting units 31 and the second light-emitting units 32 in two adjacent light-emitting unit groups 300 are different.

In the first direction D1, a plurality of the first light-emitting units 31 and a plurality of the second light-emitting units 32 are alternately arranged, and the long-side direction of two adjacent first light-emitting units 31 is perpendicular to the long-side direction of the second light-emitting units 32.

Specifically, in the embodiments of the present application, in the first direction D1, the connection line L4 between the center of the first light-emitting unit 31 and the center of the second light-emitting unit 32 is parallel to the first direction D1.

In the second direction D2, the connection line L3 between the center of the first light-emitting unit 31 and the center of the second light-emitting unit 32 is parallel to the second direction D2.

Specifically, in the first direction D1, the light emission pattern of the first light-emitting unit 31 and the light emission patterns of the two first light-emitting units 31 adjacent thereto have overlapping portions S3. In the second direction D2, the light emission pattern of the first light-emitting unit 31 and the light emission patterns of the two second light-emitting units 32 adjacent thereto have overlapping portions S4. With respect to Example 1 of the present application, in the present example of the present application, the area of the overlapped portion S1 of the light emission pattern of the second light-emitting unit 32 is further increased in the first direction D1, and at the same time, the area of the overlapped portion S2 of the light emission pattern of the first light-emitting unit 31 is further decreased in the second direction D2. So, the overlapped areas, which are in the first direction D1, of the light emission patterns of at least a part of the first light-emitting units 31 and the light emission patterns of the second light-emitting units 32 adjacent thereto are approximately consistent with the overlapped areas, which are in the second direction D2, of the light emission patterns of at least the part of the first light-emitting units 31 and the light emission patterns of the second light-emitting units 32 adjacent thereto.

In Example 2 of the present application, compared with Example 1 of the present application, in the first direction D1, the plurality of the first light-emitting units 31 and the plurality of the second light-emitting units 32 are alternately arranged, so that a long-side direction of adjacent two first light-emitting units 31 is perpendicular to a long-side direction of the second light-emitting units 32. In the first direction D1, the connection line L4 between the center of the first light-emitting unit 31 and the center of the second light-emitting unit 32 is parallel to the first direction D1. In the second direction D2, the connection line L3 between the center of the first light-emitting unit 31 and the center of the second light-emitting unit 32 is parallel to the second direction D2. So, an elliptical light spot emitted by the first light-emitting unit 31 may intersect and complement elliptical light spots emitted by at least adjacent four second light-emitting units 32, thereby making the overall light emission of the display backplane more uniform.

### EXAMPLE 3

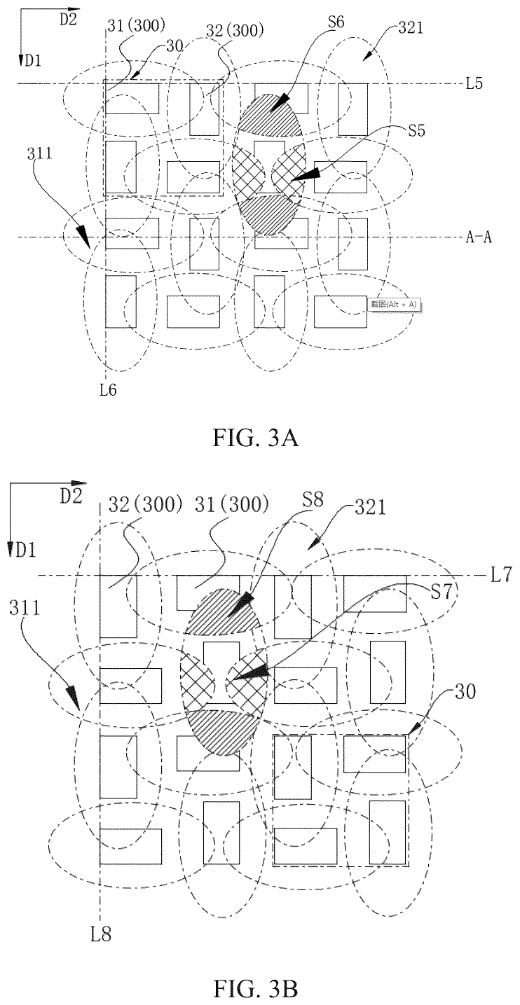

Referring to FIG. 3A, FIG. 3A is yet another partial schematic diagram of a light-emitting unit of a display backplane according to an embodiment of the present invention. The structure of the display backplane in Example 3 of the present application is the same as or similar to that of the display backplane in Example 2 of the present application, except that the light-emitting layer includes a plurality of repeating units 30 each including two first light-emitting units 31 and two second light-emitting units 32.

In each of the repeating units 30, one first light-emitting unit 31 and one second light-emitting units 32 are sequentially arranged in the first direction D1; one first light-emitting units 31 and one second light-emitting units 32 are sequentially arranged in the second direction D2.

Specifically, in the first direction D1, a connection line L6 in each of the repeating units 30 is aligned in the first direction D1, and the connection line L6 is formed by a short side of one first light-emitting unit 31 which is away from the other first light-emitting unit 31 and a long side of the second light-emitting unit 32 (which is adjacent to the one first light-emitting unit 31) which is away from the other second light-emitting units 32.

In the second direction D2, a connection line L5 is aligned in the second direction D2, and the connection line L5 is formed by a long side of one first light-emitting unit 31 which is away from the other light-emitting unit 31 and a short side of the second light-emitting unit 32 (which is adjacent to the one first light-emitting units 31) which is away from the other first light-emitting unit 31.

Specifically, in the first direction D1, the light emission pattern of the first light-emitting unit 31 and the light emission patterns of the two first light-emitting units 31 adjacent thereto have overlapping portions S5. In the second direction D2, the light emission pattern of the first light-emitting unit 31 and the light emission patterns of the two second light-emitting units 32 adjacent thereto have overlapping portions S6. With respect to Example 2 of the present application, in the present example of the present application, the area of the overlapping portion S5 of the light emission pattern of the second light-emitting unit 32 is further increased in the first direction D1, and at the same time, the area of the overlapping portion S6 of the light emission pattern of the first light-emitting unit 31 is further decreased in the second direction D2, so that the overlapping areas, which are in the first direction D1, of the light emission patterns of at least a part of the first light-emitting units 31 and the light emission patterns of the second light-emitting units 32 adjacent thereto are approximately consistent with the overlapping areas, which are in the second direction D2, of the light emission patterns of at least the part of the first light-emitting units 31 and the light emission patterns of the second light-emitting units 32 adjacent thereto.

Referring to FIG. 3B, FIG. 3B is yet another partial schematic diagram of a light-emitting unit of a display backplane according to an embodiment of the present application. In each of the repeating units 30, one second light-emitting unit 32 and one first light-emitting unit 31 are sequentially arranged in the first direction D1; and one second light-emitting unit 32 and one first light-emitting unit 31 are sequentially arranged in the second direction D2.

Specifically, in the first direction D1, a connection line L8 is aligned in the first direction D1, and the connection line L8 is formed by a long side of one second light-emitting unit 32 which is away from the other second light-emitting unit 32 and a short side of the first light-emitting unit 31 (which is adjacent to the one second light-emitting unit 32) which is away from the other second light-emitting unit 32.

In the second direction D2, a connection line L7 is aligned in the second direction D2, and the connection line L7 is formed by a short side of one second light-emitting unit 32 which is away from the other second light-emitting unit 32 and a long side of the first light-emitting unit 31 (which is adjacent to the one second light-emitting units 32) which is away from the other first light-emitting unit 31.

Specifically, in the first direction D1, the light emission pattern of the second light-emitting unit 32 and the light emission patterns of the two first light-emitting units 31 adjacent thereto have overlapping portions S8. In the second direction D2, the light emission pattern of the second light-emitting unit 32 and the light emission patterns of the two first light-emitting units 31 adjacent thereto have overlapping portions S7. With respect to Example 2 of the present application, in the first direction D1, the areas of the overlapping portions S8 of the light emission pattern of the second light-emitting unit 32 and the light emission patterns of the adjacent two first light-emitting units 31 are further increased, while in the second direction D2, the areas of the overlapping portions S7 of the light emission pattern of the second light-emitting unit 32 and the light emission patterns of the adjacent two first light-emitting units 31 are further decreased. So, the overlapping areas of the light emission patterns, which are in the first direction D1, of at least a part of the second light-emitting units 32 and the light emission patterns of the first light-emitting units 31 adjacent thereto are approximately consistent with the overlapping areas, which are in the second direction D2, of the light emission patterns of at least the part of the second light-emitting units 32 and the light emission patterns of the first light-emitting units 31 adjacent thereto.

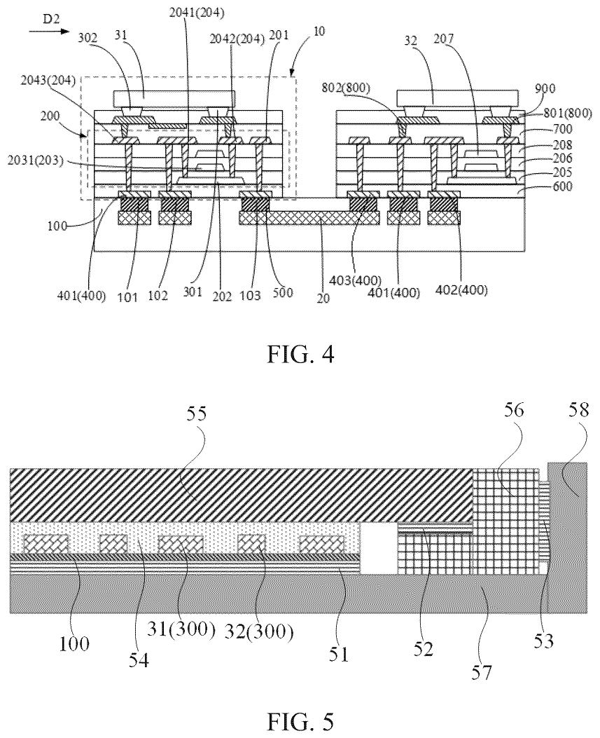

Referring to FIG. 4, FIG. 4 is a cross-sectional view of the backplane taken along line A-A in FIG. 3A. The display backplane includes a plurality of pixel islands 10. Each pixel island 10 includes a substrate 100 and a driving circuit layer 200. The substrate 100 includes a first through-hole 101. The driving circuit layer 200 is located on the substrate 100. The driving circuit layer 200 at least includes a connection electrode 201 corresponding to the first through-hole 101. The display backplane further includes a connection conductive wire 20 located on a side of the substrate 100 remote from the driving circuit layer 200. The connection electrodes 201 of two adjacent pixel islands 10 are electrically connected to two ends of the connection conductive wire 20 through corresponding first through holes 101, respectively.

In one embodiment, the drive circuit layer 200 includes an active layer 202, a first metal layer 203, and a second metal layer 204. The active layer 202 is located on the substrate 100. The first metal layer 203 is located on the active layer 202. The first metal layer 203 includes a gate electrode 2031. The second metal layer 204 includes a source electrode 2041, a drain electrode 2042, and a power supply line 2043.

The source electrode 2041 and the drain electrode 2042 are electrically connected to two ends of the active layer 202, respectively;

The substrate 100 is provided with a second through-hole 102 and a third through-hole 103. The source electrode 2041 is electrically connected to the connection conductive wire 20 through the second through-hole 102. The power supply line 2043 is electrically connected to the connection conductive wire 20 through the third through-hole 103.

In the present embodiment, the material of the active layer 202 is polysilicon. A first contact terminal 301 is electrically connected to a N-type semiconductor inside the light-emitting unit. A second contact terminal 302 is electrically connected to a P-type semiconductor inside the light-emitting unit.

It will be appreciated that in the present embodiment, the second through-hole 102 and the third through-hole 103 are provided on the substrate 100, so that the source electrode 2041 and the power supply line 2043 may be electrically connected to the connection conductive wire 20 through the second through-hole 102 and the third through-hole 103, respectively. In this way, the electrical signal is transmitted to the source electrode 2041 and the power supply line 2043 through the connection conductive wire 20. That is, the display backplane may be supplied with power from a lower portion of the pixel island 10 by using the connection conductive wire 20 which is preferably malleable.

In one embodiment, each of the pixel islands 10 is provided with the first light-emitting unit 31 or the second light-emitting unit 32, respectively. The first light-emitting unit 31 or the second light-emitting unit 32 is located on the driving circuit layer 200. The first light-emitting unit 31 or the second light-emitting unit 32 includes a first contact terminal 301 and a second contact terminal 302. The first contact terminal 301 is electrically connected to the drain electrode 2042, and the second contact terminal 302 is electrically connected to the power supply line 2043.

Note that in the same light-emitting unit group 300, a light-emitting color of the first light-emitting unit 31 is the same as a light-emitting color of the second light-emitting unit 32. That is, one pixel island 10 may include any one of a red sub-pixel, a blue sub-pixel, a green sub-pixel, and a white sub-pixel. That is, one pixel island 10 may include any one of a red light-emitting component, a green light-emitting component, a blue light-emitting component, and a white light-emitting component.

In one embodiment, the connection electrode 201 is disposed in the same layer as the second metal layer 204. It should be noted that the connection electrode 201 is used to communicate two adjacent pixel islands 10, that is, to transmit an electrical signal between the two adjacent pixel islands 10. By arranging the connection electrodes 201 and the second metal layer 204 in the same layer, the connection electrodes 201 and the second metal layer 204 may be manufactured in the same process without adding an additional photomask process, so that the production cost does not increase.

In one embodiment, a conductive layer 400 is provided on a side surface of the substrate 100 which is adjacent to the driving circuit layer 200. The conductive layer 400 includes a plurality of first conductive terminals 401, a plurality of second conductive terminals 402, and a plurality of third conductive terminals 403. The first conductive terminals 401 are provided corresponding to the first through-holes 101. The second conductive terminals 402 are provided corresponding to the second through-holes 102. The third conductive terminals 403 are provided corresponding to the third through-holes 103.

It is understood that the connection electrodes 201, the source electrodes 2041, and the power supply line 2043 are all connected to the surface of the substrate 100 through the via holes. The pore sizes of the via holes are small. So, contact areas of the connection electrode 201, the source electrode 2041, and the power supply line 2043 with the connection conductive wire 20 are smaller, and the contact impedance therebetween is larger. In this example, the plurality of first conductive terminals 401, the plurality of second conductive terminals 402, and the plurality of third conductive terminals 403 are provided on the side surface of the substrate 100 which is close to the driving circuit layer 200, and the connection electrode 201, the source electrode 2041, and the power supply line 2043 are electrically connected to the connection conductive wire 20 through the conductive terminals, so as to reduce contact impedance and voltage drop.

Further, in one embodiment, an area of the first conductive terminal 401 in a direction perpendicular to the substrate 100 is larger than an area of the second conductive terminal 402 in the direction perpendicular to the substrate 100. This is because the power supply line 2043 is electrically connected to the second contact terminal 302 (the second conductive terminal 402 is not electrically connected to the second contact terminal 302) while being electrically connected to the first conductive terminal 401, so that the contact impedance between the first conductive terminal 401 and the connection conductive wire 20 is larger than the contact impedance between the second conductive terminal 402 and the connection conductive wire 20. Therefore, the area of the first conductive terminal 401 in the direction perpendicular to the substrate 100 is increased to reduce the contact impedance and reduce the voltage drop.

In one embodiment, the first through-hole 101, the second through-hole 102, and the third through-hole 103 are filled with conductive material 500. It will be appreciated that in this embodiment, the conductive material 500 is filled in the first through-hole 101, the second through-hole 102, and the third through-hole 103 to improve the conductive effect of the connection electrode 201, the source electrode 2041, and the power supply line 2043 and the connection conductive wire 20.

In one embodiment, the display backplane further includes a buffer layer 600, a passivation layer 700, a third metal layer 800, and an insulating layer 900. The buffer layer 600 is located between the substrate 100 and the driving circuit layer 200.

The passivation layer 700 is located on the second metal layer 204. The third metal layer 800 is located on the passivation layer 700. The insulating layer 900 is located between the third metal layer 800 and the first light-emitting unit 31 or the second light-emitting unit 32. The third metal layer 800 includes a plurality of first conductive electrodes 801 and a plurality of second conductive electrodes 802. The first contact terminal 301 of the first light-emitting unit 31 or the second light-emitting unit 32 is electrically connected to the drain electrode 2042 through the first conductive electrode 801. The second contact terminal 302 of the first light-emitting unit 31 or the second light-emitting unit 32 is electrically connected to the power supply line 2043 through the second conductive electrode 802.

In one embodiment, the driver circuit layer 200 further includes a first gate insulating layer 205 located between the active layer 202 and the first metal layer 203, a second gate insulating layer 206 located on the first metal layer 203, a second gate layer 207 located on the second gate insulating layer 206, and an interlayer insulating layer 208 located on the second gate layer 207. The second metal layer 204 is located between the interlayer insulating layer 208 and the passivation layer 700.

In the embodiments of the present application, the first contact terminal 301 and the second contact terminal 302 in the first light-emitting unit 31 are arranged differently from the first contact terminal 301 and the second contact terminal 302 in the second light-emitting unit 32.

Specifically, the first contact terminal 301 and the second contact terminal 302 in the first light-emitting unit 31 and the first contact terminal 301 and the second contact terminal 302 in the second light-emitting unit 32 are arranged in the second direction D2 (that is, two contact terminals in the first light-emitting unit 31 are arranged in the long-side direction, and two contact terminals in the second light-emitting unit 32 are arranged in the short-side direction).

The distance between the first contact terminal 301 and the second contact terminal 302 in the first light-emitting unit 31 is greater than the distance between the first contact terminal 301 and the second contact terminal 302 in the second light-emitting unit 32. Thus, since the size of the short side is smaller than that of the long side, the distance between the two contact terminals arranged in the short-side direction is correspondingly reduced.

In another embodiment of the present application, the first contact

terminal 301 and the second contact terminal 302 in the first light-emitting unit 31 and the first contact terminal 301 and the second contact terminal 302 in the second light-emitting unit 32 are arranged in the first direction D1 (that is, two contact terminals in the first light-emitting unit 31 are arranged in the short-side direction and two contact terminals in the second light-emitting unit 32 are arranged in the long-side direction).

The distance between the first contact terminal 301 and the second contact terminal 302 in the first light-emitting unit 31 is smaller than the distance between the first contact terminal 301 and the second contact terminal 302 in the second light-emitting unit 32. Thus, since the size of the short side is smaller than that of the long side, the distance between the two contact terminals arranged in the short-side direction is correspondingly reduced.

In another embodiment of the present application, the first contact terminal 301 and the second contact terminal 302 in the first light-emitting unit 31 are arranged in the second direction D2, and the first contact terminal 301 and the second contact terminal 302 in the second light-emitting unit 32 are arranged in the first direction D1 (that is, two contact terminals in the first light-emitting unit 31 are arranged in the long-side direction, and two contact terminals in the second light-emitting unit 32 are also arranged in the long-side direction).

Compared with Example 2 of the present application, in Example 3 of the present application, an overlapping areas, which are in the first direction D1, of the light emission pattern of the first light-emitting unit 31 and the light emission patterns of at least adjacent four second light-emitting units 32 are approximately consistent with overlapping areas, which are in the second direction D2, of the light emission pattern of the first light-emitting unit 31 and the light emission patterns of at least adjacent four second light-emitting units 32. In this way, elliptical light spots emitted by the first light-emitting unit 31 and elliptical light spots emitted by at least adjacent four second light-emitting units 32 may more evenly intersect and complement with each other, thereby making the overall light emission of the display backplane more uniform.

Referring to FIG. 5, FIG. 5 is a partial schematic diagram of a display backplane according to an embodiment of the present application. The display backplane is used to provide a backlight for the display device.

Specifically, the display backplane includes a bottom plate 57 and a side plate 58 integrally formed with the bottom plate 57. A side of the bottom plate 100 remote from the first light-emitting unit 31 or the second light-emitting unit 32 is bonded to the bottom plate 57 by a first adhesive 51. The bottom plate 57 is further provided with a first encapsulation layer 54. The first encapsulation layer 54 is completely covers the first light-emitting units 31 and the second light-emitting units 32. A side of the first encapsulation layer 54 remote from the substrate 100 is further provided with an optical film group 55. The optical film group 55 includes one or more of an anti-red-green film, a quantum dot film, a light-splitting film, a brightness enhancing film, a diffusion film, and the like, each of which is arbitrary in number, size, and collocation, depending on the actual effect.

Further, a side of the bottom plate 57 remote from the substrate 100 is further provided with a second encapsulation layer 56. An end of the second encapsulation layer 56 is bonded to the optical film group 55 by a second adhesive 52, and the other end of the second encapsulation layer 56 is bonded to the side plate 58 by a third adhesive 53.

Accordingly, the present application further provides a display device including a display body and the display backplane. The display body and the display backplane are integrated. The display device may include, but is not limited to, a mobile phone, a tablet computer, a computer display, a game machine, a television, a display screen, a wearable device, and other household appliances or household appliances having a display function.

It should be noted that only the main structure of the display backplane is shown in FIGS. 1 to 5. A film layer such as a module chip, a flexible circuit board, a polarizing plate, a protective film, or the like included in the final form of the display device is not shown, but the final form of the display terminal may include this film layer. This film layer may be manufactured in or after the end of the manufacturing process flow of the display backplane provided in the embodiments of the present invention, which will not be described in detail herein.

The present application provides a display backplane and a display device in view of the technical problem of uneven light mixing of light-emitting unit groups 300 in a conventional display backplane. The display backplane includes a substrate 100 and a light-emitting layer disposed on the substrate 100. The light-emitting layer includes a plurality of light-emitting unit groups 300 arranged in a first direction D1. The light-emitting unit group 300 includes a plurality of first light-emitting units 31 and a plurality of second light-emitting units 32 arranged alternately in a second direction D2. Sizes of the first light-emitting units 31 in the first direction D1 are larger than sizes of the second light-emitting units 32 in the first direction D1, and sizes of the first light-emitting units 31 in the second direction D2 are smaller than sizes of the second light-emitting units 32 in the second direction D2. According to the display backplane provided in the present application, the size of the first light-emitting unit 31 in the first direction D1 is larger than the size of the second light-emitting unit 32 in the first direction D1, and the size of the first light-emitting unit 31 in the second direction D2 is smaller than the size of the second light-emitting unit 32 in the second direction D2, so that the long-side direction of the plurality of the first light-emitting units 31 is perpendicular to the long-side direction of the plurality of the second light-emitting units 32. So, the overlapping areas, which are in the first direction D1, of the light emission patterns of at least a part of the first light-emitting units 31 and the light emission patterns of the second light-emitting units 32 adjacent thereto are approximately consistent with the overlapping areas, which are in the second direction D2, of the light emission patterns of at least a part of the first light-emitting units 31 and the light emission patterns of the second light-emitting units 32 adjacent thereto. Accordingly, the overall light emission of the display backplane is more uniform, thereby reducing a shadow area formed by insufficient illumination, avoiding the problem that the display backplane is uneven in brightness and darkness, and further improving the light emission effect of the display backplane.

In light of the foregoing, although the present application has been disclosed in preferred embodiments, the above preferred embodiments are not intended to limit the present application. Those of ordinary skill in the art may make various changes and modifications without departing from the spirit and the scope of the present application, and therefore the protection scope of the present application is based on the scope defined in the claims.

1. A display backplane comprising:
a substrate; and
a light-emitting layer disposed on the substrate, the light-emitting layer comprising a plurality of light-emitting unit groups arranged in a first direction, wherein each of the light-emitting unit groups comprises a plurality of first light-emitting units and a plurality of second light-emitting units arranged alternately in a second direction;
wherein sizes of the plurality of first light-emitting units in the first direction are greater than sizes of the plurality of second light-emitting units in the first direction, and sizes of the plurality of first light-emitting unit in the second direction are less than sizes of the plurality of second light-emitting units in the second direction.

2. The display backplane according to claim 1, wherein ones of the plurality of first light-emitting units and ones of the plurality of second light-emitting units in adjacent two of the plurality of light-emitting unit groups are arranged in a same manner.

3. The display backplane according to claim 1, wherein ones of the plurality of first light-emitting units and ones of the plurality of second light-emitting units in adjacent two of the plurality of light-emitting unit groups are arranged differently;
wherein the ones of the plurality of first light-emitting units and the ones of the plurality of second light-emitting units are alternately arranged in the first direction, and a long-side direction of each of the ones of the plurality of first light-emitting units is perpendicular to a long-side direction of an adjacent one of the ones of the plurality of second light-emitting units.

4. The display backplane according to claim 3, wherein a connection line between a center of each of the plurality of first light-emitting units and a center of a corresponding one of the plurality of second light-emitting units in the first direction is parallel to the first direction; and
a connection line between the center of the first light-emitting unit and the center of the corresponding one of the plurality of second light-emitting unit in the second direction is parallel to the second direction.

5. The display backplane according to claim 3, wherein the light-emitting layer comprises a plurality of repeating units each of which comprises two of the plurality of first light-emitting units and two of the plurality of second light-emitting units;
wherein in each of the plurality of repeating units, in the first direction, a short side of one of the two first light-emitting units that is away from an other one of the two first light-emitting units and a long side of one of the two second light-emitting units adjacent to the one of the two first light-emitting units are aligned in the first direction, wherein the long side is away from an other one of the two second light-emitting units;
in the second direction, a long side of one of the two first light-emitting units which is away from the other one of the two first light-emitting units and a short side of one of the two second light-emitting units which is adjacent to the one of the two first light-emitting units are aligned in the second direction, wherein the short side of the one of the two second light-emitting units is away from the other one of the two second light-emitting units.

6. The display backplane according to claim 1, wherein a distance between adjacent two of the plurality of first light-emitting units in the first direction is equal to a distance between each of the plurality of first light-emitting units and an adjacent one of the plurality of second light-emitting units in the second direction.

7. The display backplane according to claim 1, wherein the display backplane further comprises a driving circuit layer disposed between the substrate and the light-emitting layer, and the driving circuit layer comprises a thin film transistor and a power supply line;
the first light-emitting units and the second light-emitting units each comprise a first contact terminal and a second contact terminal, wherein the first contact terminal is electrically connected to a source electrode or a drain electrode of the thin film transistor, and the second contact terminal is electrically connected to the power supply line;
wherein the first contact terminal and the second contact terminal in the first light-emitting unit are arranged differently from the first contact terminal and the second contact terminal in the second light-emitting unit.

8. The display backplane according to claim 7, wherein the first contact terminal and the second contact terminal in the first light-emitting unit and the first contact terminal and the second contact terminal in the second light-emitting unit are arranged in the first direction or the second direction;
wherein a distance between the first contact terminal and the second contact terminal in the first light-emitting unit is greater than a distance between the first contact terminal and the second contact terminal in the second light-emitting unit.

9. The display backplane according to claim 7, wherein the first contact terminal and the second contact terminal in the first light-emitting unit are arranged in the second direction, and the first contact terminal and the second contact terminal in the second light-emitting unit are arranged in the first direction.

10. The display backplane according to claim 1, wherein an aspect ratio of each of the first light-emitting units or an aspect ratio of each of the second light-emitting units is greater than 1.5:1.

11. A display device comprising a display backplane, the display backplane comprising:
a substrate; and
a light-emitting layer disposed on the substrate, the light-emitting layer comprising a plurality of light-emitting unit groups arranged in a first direction, wherein each of the light-emitting unit groups comprises a plurality of first light-emitting units and a plurality of second light-emitting units arranged alternately in a second direction;
wherein sizes of the plurality of first light-emitting units in the first direction are greater than sizes of the plurality of second light-emitting units in the first direction, and sizes of the plurality of first light-emitting unit in the second direction are less than sizes of the plurality of second light-emitting units in the second direction.

12. The display device according to claim 11, wherein ones of the plurality of first light-emitting units and ones of the plurality of second light-emitting units in adjacent two of the plurality of light-emitting unit groups are arranged in a same manner.

13. The display device according to claim 11, wherein ones of the plurality of first light-emitting units and ones of the plurality of second light-emitting units in adjacent two of the plurality of light-emitting unit groups are arranged differently;
wherein the ones of the plurality of first light-emitting units and the ones of the plurality of second light-emitting units are alternately arranged in the first direction, and a long-side direction of each of the ones of the plurality of first light-emitting units is perpendicular to a long-side direction of a corresponding an adjacent one of the ones of the plurality of second light-emitting units.

14. The display device according to claim 13, wherein a connection line between a center of each of the plurality of first light-emitting units and a center of a corresponding one of the plurality of second light-emitting units in the first direction is parallel to the first direction; and
a connection line between the center of the first light-emitting unit and the center of the corresponding one of the plurality of second light-emitting unit in the second direction is parallel to the second direction.

15. The display device according to claim 13, wherein the light-emitting layer comprises a plurality of repeating units each of which comprises two of the plurality of first light-emitting units and two of the plurality of second light-emitting units;
wherein in each of the plurality of repeating units, in the first direction, a short side of one of the two first light-emitting units that is away from an other one of the two first light-emitting units and a long side of one of the two second light-emitting units adjacent to the one of the two first light-emitting units are aligned in the first direction, wherein the long side is away from an other one of the two second light-emitting units;
in the second direction, a long side of one of the two first light-emitting units which is away from the other one of the two first light-emitting units and a short side of one of the two second light-emitting units which is adjacent to the one of the two first light-emitting units are aligned in the second direction, wherein the short side of the one of the two second light-emitting units is away from the other one of the two second light-emitting units.

16. The display device according to claim 11, wherein a distance between adjacent two of the plurality of first light-emitting units in the first direction is equal to a distance between each of the plurality of first light-emitting units and an adjacent one of the plurality of second light-emitting units in the second direction.

17. The display device according to claim 11, wherein the display backplane further comprises a driving circuit layer disposed between the substrate and the light-emitting layer, and the driving circuit layer comprises a thin film transistor and a power supply line;
the first light-emitting units and the second light-emitting units each comprise a first contact terminal and a second contact terminal, wherein the first contact terminal is electrically connected to a source electrode or a drain electrode of the thin film transistor, and the second contact terminal is electrically connected to the power supply line;
wherein the first contact terminal and the second contact terminal in the first light-emitting unit are arranged differently from the first contact terminal and the second contact terminal in the second light-emitting unit.

18. The display device according to claim 17, wherein the first contact terminal and the second contact terminal in the first light-emitting unit and the first contact terminal and the second contact terminal in the second light-emitting unit are arranged in the first direction or the second direction;
wherein a distance between the first contact terminal and the second contact terminal in the first light-emitting unit is greater than a distance between the first contact terminal and the second contact terminal in the second light-emitting unit.

19. The display device according to claim 17, wherein the first contact terminal and the second contact terminal in the first light-emitting unit are arranged in the second direction, and the first contact terminal and the second contact terminal in the second light-emitting unit are arranged in the first direction.

20. The display device according to claim 11, wherein an aspect ratio of each of the first light-emitting units or an aspect ratio of each of the second light-emitting units is greater than 1.5:1.
